(19) United States
(12) Patent Application Publication
(10) Pub. No.: US 2011/0156239 A1
(43) Pub. Date: Jun. 30, 2011

(54) METHOD FOR MANUFACTURING A FAN-OUT EMBEDDED PANEL LEVEL PACKAGE

(75) Inventor: Yonggang Jin, Singapore (SG)

(73) Assignee: STMICROELECTRONICS ASIA PACIFIC PTE LTD., Singapore (SG)

(21) Appl. No.: 12/649,118

(22) Filed: Dec. 29, 2009

(51) Int. Cl. H01L 23/498; H01L 21/78

(52) U.S. Cl. 257/692; 438/113; 257/E21.599; 257/E23.07

(57) ABSTRACT

A method for manufacturing a fan-out embedded panel-level package. Film having an adhesive on each side is applied to the non-active face of a plurality of semiconductor die while the die are still in wafer form. The die are singulated from the wafer and placed on a carrier, using the adhesive on the unused side of the film to attach the die to the carrier. Encapsulant material is dispensed onto the carrier adjacent to the die, providing an exposed surface on the encapsulant material approximately even with the active faces of the die. Elements of the redistribution layer such as conductors and fan-out pads are applied to this surface. A solder ball array is placed on the fan-out pads and then the die are re-singulated by cutting through the encapsulation material and the carrier, yielding individual electronic packages.

### BACKGROUND

1. Technical Field

This description generally relates to the field of electronic packaging and, in particular, to methods for making semiconductor electronic packages.

2. Description of the Related Art

Due to the circuit density of semiconductor die, the electrical connection pads from a die's active face are usually fanned out to a lower density for interface with external circuits. Fan-out is accomplished by printing a re-distribution layer on the face of the encapsulated die. The re-distribution layer provides conductors that extend from the pads on the die's active face to less dense pad arrangement on an exposed face of the re-distribution layer. The less dense interface accommodates larger-scale interface methods, such as a ball grid array, that cannot interface with a semiconductor die directly.

One step in the packaging technique is printing of the conducting and insulating layers of the re-distribution layer on the die after encapsulation. In the existing art, bare die are singulated from a wafer and the die placed on a carrier with the active face of the die against the carrier. On the carrier an encapsulant material is dispensed over the die and then cured. The tape carrier is then removed, re-exposing the die's active face. The insulating layers and conductive traces of the re-distribution layer are printed on the die's active face, extending out onto the encapsulation material as needed. A passivation layer is usually applied to the re-distribution layer and then balls of a ball grid array are placed on the larger pads of the re-distribution layer. Singulation of the individual packages from the encapsulation materials follows.

Two disadvantages of this packaging technique are the extra step involved in removing the carrier from the die and the sometimes difficult operation of removing leftover adhesive from the active face of the die.

### BRIEF SUMMARY

According to one embodiment of the invention, a film having an adhesive on each side is applied to the non-active face of a plurality of semiconductor die while the die are still in wafer form. Next the plurality of die are singulated using any one of a number of techniques known in the art. In this step, the singulating cuts pass through both the semiconductor wafer and the applied film. Next the plurality of die are placed on a carrier, using the adhesive of the unused side of the film to attach the die to the carrier. Next, a selected amount of an encapsulant material is dispensed in fluid form onto the carrier adjacent to the die, which after solidification, provides a surface on the encapsulant material that is approximately even with the active face of the die.

Next, fan-out, insulation pads are applied to the encapsulant material surface. Next, conductive traces are applied to both the encapsulant material surface and the active die face to connect the fan-out pads to electrical connection pads on the active die face. Additional, insulating layers and passivation layers may also be applied to the encapsulant material surface and the active die face, as needed, before or after these steps. Application of the fan-out pads, conductive traces, insulating layer, and passivation layers may be applied using any one of a number of techniques known in the art, such as screen printing.

Next, solder balls of a ball grid array are placed on the applied fan-out pads. Next, the plurality of die may be singulated if the plurality of die placed on the carrier are intended to make up individual electronic packages. The die are singulated by cutting through both the encapsulant material and the carrier. This raises two advantages of the process: (1) the step in the prior art of removing the carrier is saved because the carrier permanently stays with the die, and (2) at no step in the method must adhesive be removed from the die because at no step is adhesive adhered to those parts of the active surface from which it must later be removed.

### BRIEF DESCRIPTION OF THE SEVERAL VIEWS OF THE DRAWINGS

FIG. 1A shows a top view of a semiconductor wafer according to the present invention.;

FIG. 1B shows a zoom view of an individual die from the semiconductor wafer of FIG. 1A;

FIG. 1C shows a side view of FIG. 1A showing a step in a method of making a fan-out embedded panel level package (package);

FIGS. 2A and 2B show a side view of a step in a method of making a fan-out package;

FIG. 3 shows a cross-sectional view of a step in a method of making a fan-out package;

FIGS. 4A and FIG. 4B show a top view and a cross-sectional view, respectively, of a step in a method of making a fan-out package;

FIG. 5A-5C show a cross-sectional view of additional steps in a method of making a fan-out package;

FIG. 6 shows a cross-sectional view of a step in a method of making a fan-out package;

FIG. 7 shows a cross-sectional view of a step in a method of making a fan-out package;

FIG. 8 shows a cross-sectional view of a final fan-out package;

### DETAILED DESCRIPTION

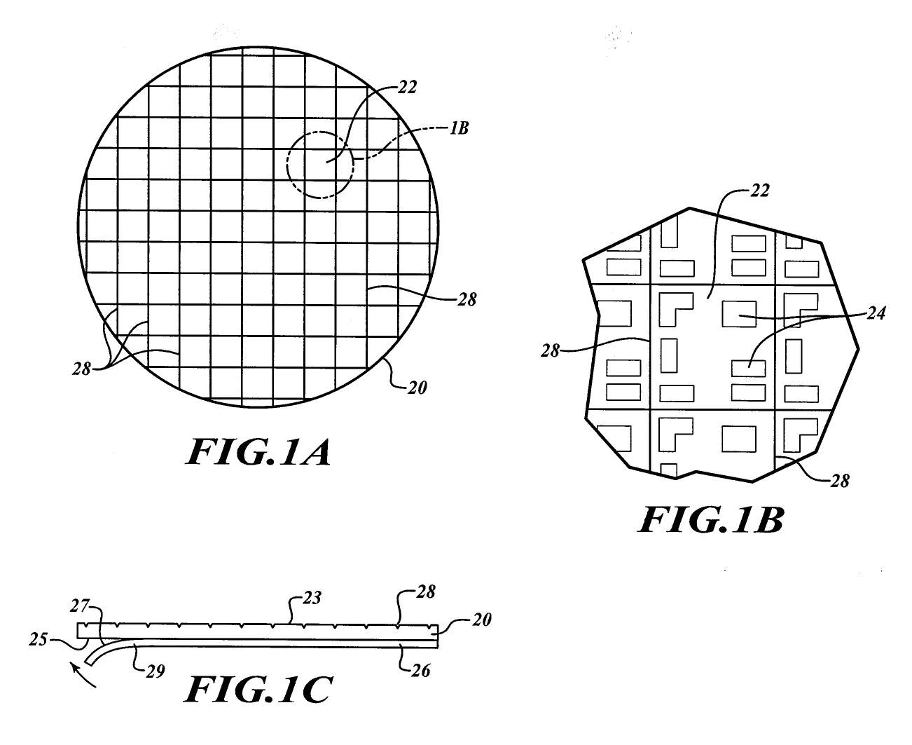

FIGS. 1A-C show a semiconductor wafer 20 of a type well known in the art, composed of individual semiconductor die 22. The die are separated by scribe lines 28. Each die 22 has an active face 23 having a plurality of electrical connection pads 24 and a non-active face 25. The active face 23 has a plurality of integrated circuits formed therein. The individual semiconductor die 22 that make up the semiconductor wafer 20 may or may not be identical over the entire semiconductor wafer 20. The pattern of the electrical connection pads 24 on the die's active face, shown in FIG. 1 B, may or may not be the same throughout the semiconductor wafer 20. The pads 24 are standard bond pads of the type well known in the art. They are shown enlarged for ease of identification.

FIG. 1C shows a step in a method of making a fan-out embedded panel level package: a first side 27 of a two-sided tape 26 is applied to each semiconductor die 22 while the die are still in wafer form. The side 29 is also an adhesive, as discussed later herein. The tape 26 is applied to the non-active face 25 of the die 22. In one embodiment, the tape 26 is attached to the die 20 by a permanent adhesive on side 27. In another embodiment, the body of the tape 26 is composed of one of a number of materials used in the field of semiconductor manufacturing and packaging, for example, a polymeric material that can be easily removed. The choices in selecting the properties of tape layer 26 will be discussed later herein.

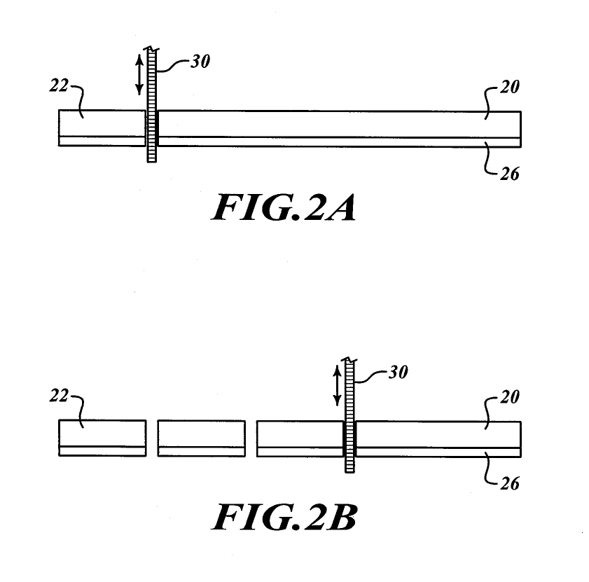

FIGS. 2A and 2B show a saw blade 30 separates the individual die 22 from the wafer 20 by progressively placing cuts across the face of the wafer 20. The saw blade 30 may be a rotating blade, but other techniques for making the cut are within the scope of the invention. The saw blade 30 cuts completely through both the semiconductor wafer 20 and the two-sided tape 26. In one embodiment, the adhesive 26 is placed on the back of individual die 22 after they are cingulated from the wafer 20.

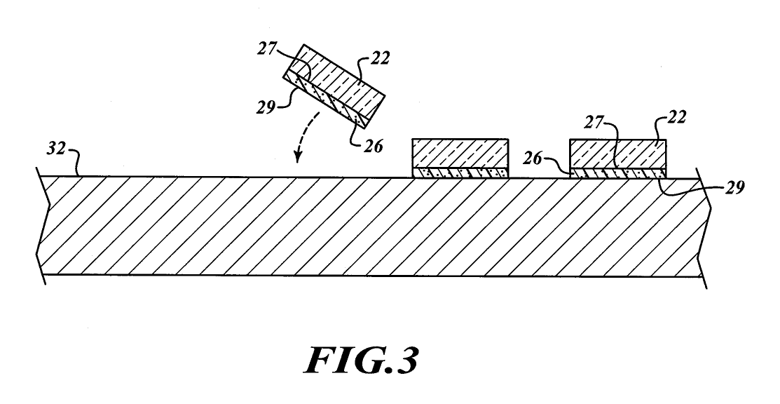

FIG. 3 shows a third step in the method of making a fan-out package: placement of the singulated semiconductor die 22 onto a carrier 32. The carrier 32 is a rectangular, rigid support made of an environmentally stable, low-cost material. In one embodiment, the carrier 32 is composed of material similar to the dielectric layers in a PC board. For example, it may comprise alternating layers of a fiberglass and epoxy resin. In other embodiments, the carrier 32 is composed of a polymer of the same type which will be used for the encapsulation material 34 discussed later herein. The encapsulation material 34 and the carrier 32 preferably bond tightly to each other in one embodiment in order to form a permanent bond. Accordingly, selecting a material for the carrier 32 which is compatible with the encapsulation layer 34 is beneficial.

In one alternative embodiment, the carrier 32 is composed of a highly thermally conductive material. For example, the carrier 32 may be composed of a copper alloy which has high thermal conductivity. As explained later herein with respect to FIG. 8, the carrier 32 may remain attached to the die 22 for the life of the die and act as a heat dissipater to quickly and easily remove heat from the die 22. Accordingly, in those embodiments in which the carrier 32 is acting as a heat dissipater, the material selected will be of a type which is compatible with heat dissipation properties. In some embodiments, this may be a copper, copper alloy, while in other embodiments it may be a resin with high thermal conductivity or some other polymer selected for both its stability, low cost, and high thermal conductivity. In this embodiment, the tape 26 is selected to have high conduction properties, compatible, of course, with its other needs.

The individual die 22 may be attached to the carrier 32 using device packaging equipment commonly known in the packaging industry, for example, a pick-and-place machine. The die 22 are placed on the carrier 32 with the second side 29 of the two-sided tape 26 against the carrier 32. As a result, the individual die 22 sit on the carrier 32 so that the electrical connection pads 24 of the die's active face are exposed.

The adhesive bond on the second side 29 of tape 26 is the same as on the first side 27 in one embodiment. If the first side 27 is a permanent, nonremovable bond, the second side 29 is also. If the first side 27 is an easily removable bond, the second side 29 is also.

In an alternative embodiment, the adhesive strength on the two sides are different. The bond on the second side 29 may be much stronger than the bond on the first side 27. This way, after the die are coupled to the carrier and molded, the die 22 can be removed and the carrier will have the adhesive 26 attached. Alternatively, the first side 27 may have a stronger bond than the second side 29.

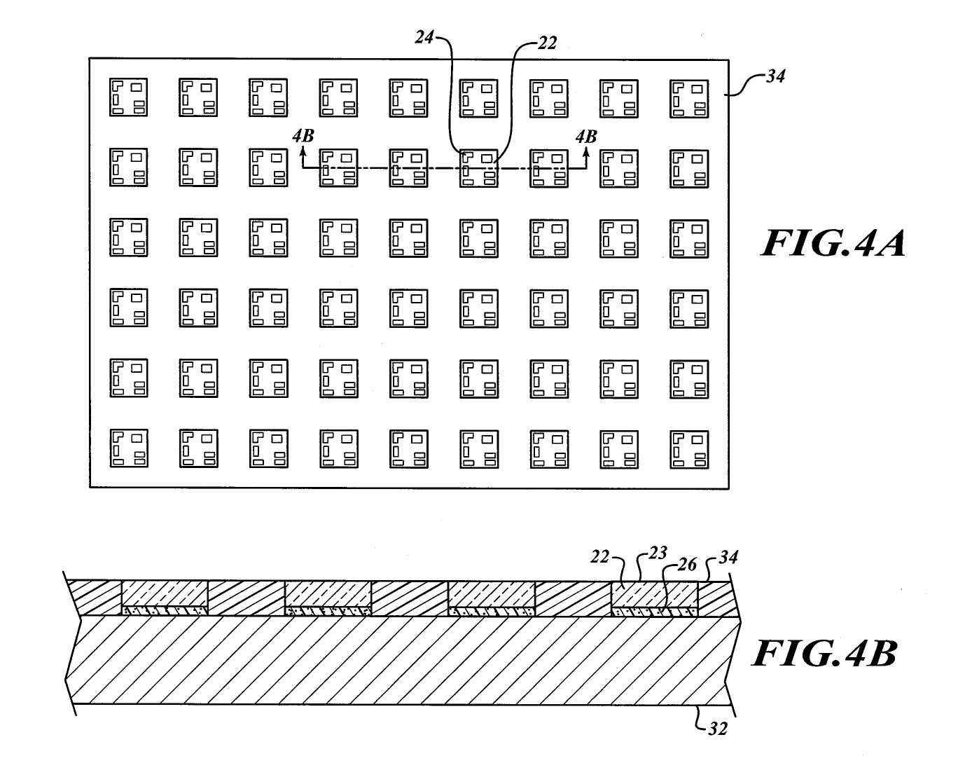

FIGS. 4A and 4B show an encapsulant 34 has been dispensed around the carrier-mounted semiconductor die 22. The encapsulant 34 is dispensed so that the exposed top face of the encapsulant is approximately even with the die's active face 23. The plurality of electrical connection pads 24 remain exposed, as shown in FIG. 4B. A number of techniques can be used to ensure that the encapsulant 36 is generally even with the active face 23 of the die 22. These include molds, precisely metering the encapsulant 34, polishing a layer off of both the die 22 and the encapsulant 34, and the like. FIGS. 4A and 4B also show that the carrier 32 is rectangular in shape, which provides benefits that will be discussed below. The encapsulant material 34 can be one of many encapsulant materials commonly known in the field.

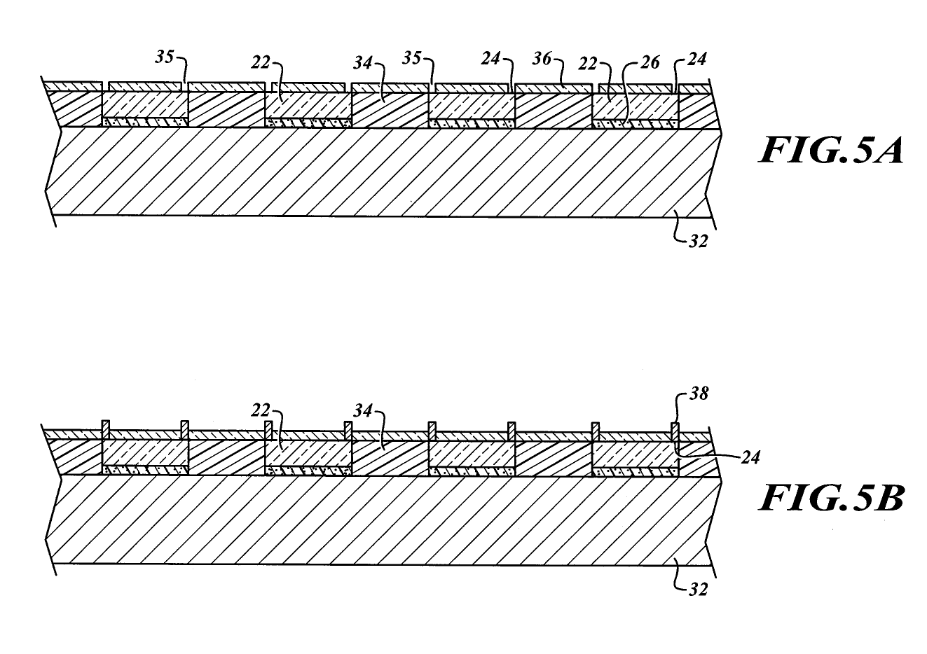

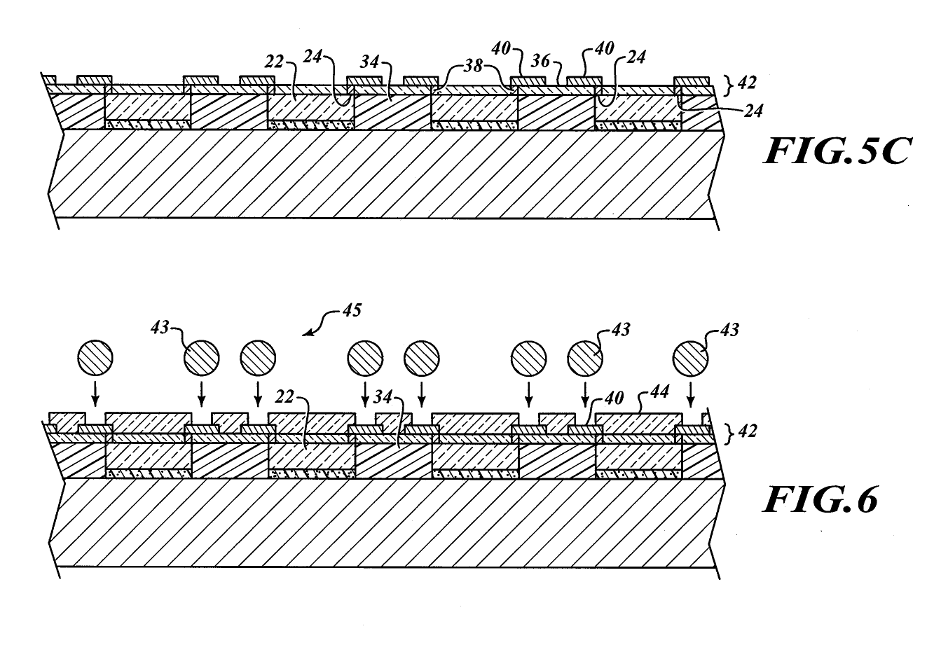

FIGS. 5A-5C show subsequent steps in the method of making expanded fan-out packages consistent with the invention. These steps include printing insulating or dielectric layers 36, conductive vias 38, and conductive metal traces 40, that together make up a re-distribution layer 42. These layers 36, 38, and 40 are applied to the exposed face of the encapsulant material 34 and the active face of the die 22.

The dielectric layer 36 is positioned overlaying the encapsulant 34 and the active face of the die 22. In one embodiment, the dielectric layer 36 is a continuous layer as deposited and, after deposition, apertures 35 are formed therein in order to provide access to the contact pads 24 on the active face of the semiconductor substrate. The apertures 35 may be opened by any acceptable technique, including wet etching, standard dielectric removal or other methods.

In one embodiment, silk screening is used to apply the layer 36 having apertures 35 therein. Silk screening can form properly located and fine openings of the size needed for contact pads 24 using silk screen techniques well known in the art. Accordingly, the layer 36 having openings 35 therein is applied using standard semiconductor silk screen techniques. Silk screening has the benefit that apertures 35 can be precisely located and the openings are created at the same time the layer 36 is applied so that additional etching is not needed. In addition, pad printing, ink jet printing, or other appropriate printing techniques may also be used to deposit dielectric layer 36 while leaving apertures 35 open for access to the contact pads 24.

Following the formation of the apertures 35, conductive vias 38 are formed in the openings 35. The conductive vias may be formed by any of a number of acceptable techniques, including a solder, paste, mask, electroplating, a solder application by maskless techniques followed by an etch and removal of excess solder, ball bonding, the insertion of a bond pad to receive a ball of a ball grid array, or any other acceptable technique.

Following the formation of the conductive vias 38 through the insulating layer 36, conductive metal traces 40 are formed in electrical contact with the conductive vias 38 as shown in FIG. 5C. The conductive tracers 40 provide electrical contact to the appropriate conductive pads 24 through the conductive vias 38. In some embodiments, the conductive traces 40 take the form of landing pads for the balls 43 of the ball grid array 45 as described with respect to FIG. 6.

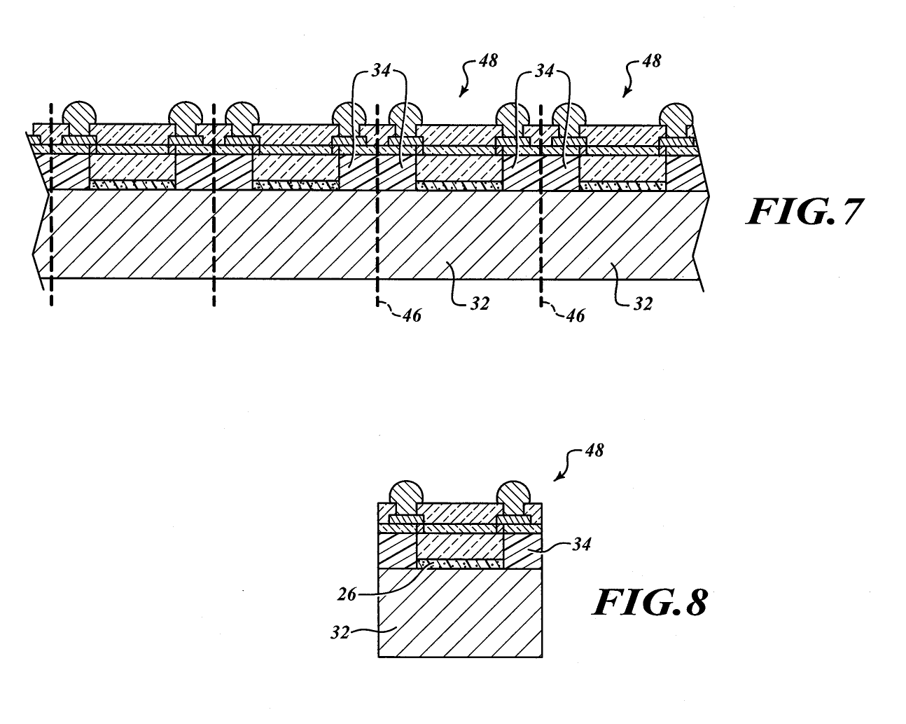

In one embodiment, balls 43 of the ball grid array are attached immediately following the formation of the conductive traces 40. In an alternative embodiment, a further dielectric layer 44 is applied to the structure by an acceptable technique such as blanket deposition and etch removal, silk screen printing, or any other acceptable technique. Together the layers 36, 40, 44 and the like form a redistribution layer 42. Of course, the redistribution layer 42 can have a number of alternating conductive and dielectric layers in order to provide the appropriate contact and connection between the various conductors associated with each die 22. While various techniques for forming the distribution layer 42 have been described, any steps well known in the art for forming such a distribution layer for coupling to the semiconductor layer 22 may be used in order to achieve the structures shown in FIG. 7.

The tape 26 may also be selected to provide some compensation for differences in the thermal coefficient of expansion. For example, if the carrier is a copper alloy, it may have a higher thermal coefficient of expansion than silicon. If it is rigidly bonded directly to the die, this may cause cracking or delamination as the chip repeatedly heats and cools. If the tape 26 has some internal flexibility, it can absorb some of the differences in size as the die and carrier expand and contract different amounts due to temperature fluctuations. The carrier 32 may also be selected to have a thermal coefficient of expansion nearly the same as that of silicon and the encapsulant 34. In this case, the tape 26 need not have any thermally flexible properties. The tape 26 should be thermal compatible with the die 22, if it is to be left attached.

FIG. 6 shows another step in the method of making expanded fan-out packages, printing the passivation layer 44 over the re-distribution layer 42 and placing balls 43 of the ball grid array 45 onto the printed conductive traces 40 of the re-distribution layer 42.

According to an alternative embodiment, the carrier 32 is removed after the structure of FIG. 6 is formed, thus leaving the encapsulated die with the adhesive 26 and the encapsulation material 34 surrounding the non-active face and the sides. In this embodiment, the adhesive 26 takes the form of that is permanently bonded to the back side of the die and merges seamlessly with the encapsulation material 34, but from which the carrier 32 ca be easily removed.

FIG. 7 shows a final step in the method of making expanded fan-out packages: singulating individual packages 48 from the common carrier 32 and the common encapsulant material 34 with singulating cuts 46.

FIG. 8 shows in a final form an individual package 48 made by the fan-out package method. Notably, a portion of both the two-sided tape 26 and the carrier 32 remain a permanent part of the package 48 according to one embodiment.

In one embodiment, the carrier 32 has a high thermal conductivity and acts as a heat sink for the die 22. Namely, the carrier 32 is composed of a material that acts as a heat sink, such as copper or other highly thermal conductive material. In this embodiment, the tape 26 permanently bonds the thermal heat sink 32 to the back side of the die 22 integral with the process of encapsulation and creating of the die. The heat sink 32 therefore remains on the die for the life of the die and provides the additional benefit of dissipating heat during operation of the die 22. In this embodiment, the adhesive 26 is a permanent adhesive which permanently bonds the die 22 to the carrier 32 and preferably is an adhesive having a high thermal conductivity. The encapsulant 34 also is selected to permanently bond the die 22 to the carrier 32 to ensure solid attachment to the die 32 for the life of the die with good thermal dissipation.

A first advantage of the disclosed method of making a fan-out package is cost reduction. Panel-level packaging is more cost effective than wafer-packaging because panel-level packaging uses rectangular-shaped carriers. A rectangular-shaped carrier has the benefit of increased area in the corners compared with a round wafer having a diameter the same length as a side of the rectangle. An additional cost benefit of a rectangular carrier is that existing processes and equipment from the printed circuit board (PCB) and the liquid crystal display (LCD) manufacturing industries can be used, rather than more expensive semiconducting processing equipment used in wafer-level packaging. Another cost benefit associated with a rectangular carrier is the ability to go to even greater panel sizes typical of PCB and LCD manufacturing compared with the limited size of semiconductor manufacturing equipment. Yet another cost benefit is the ability to access less expensive process materials and to decrease the number of processing steps.

An advantage of the present method compared with the prior art in the background section is elimination of the “flying die” problem. A “flying die” is the occurrence of a die moving out of position on the carrier during the step where encapsulation material is dispensed onto the carrier. In the prior art method, the active face of the semiconductor die is fixed to a carrier using a temporary adhesive that allows the carrier to be removed in a later step. The likelihood of a die detaching itself from the carrier is increased by using a temporary adhesive. In the disclosed method, because the die is permanently mounted to the carrier, a strong, permanent adhesive can be used for both sides of the two-sided tape 26. This leads to a lower rate of occurrence of die moving on the carrier during the encapsulation step compared with the prior art method. A second adhesive-related advantage over the prior art is that no adhesive residue is left behind on the active face of the die. This is the case because in the present method, the carrier is attached to the die's non-active face, rather than the active face, as in the prior art. In the package method, no adhesive is applied to the active face of the die.

Another advantage over the prior art is a reduction in the number of process steps, in particular the step of removing a temporary carrier from the die. Yet another advantage is that no grinding of encapsulant material is required, as in the prior art method, eliminating the risk of damaging die during a grinding operation.

The various embodiments described above can be combined to provide further embodiments. All of the U.S. patents, U.S. patent application publications, U.S. patent application, foreign patents, foreign patent application and non-patent publications referred to in this specification and/or listed in the Application Data Sheet are incorporated herein by reference, in their entirety. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for making an apparatus, comprising:
adhering a first side of a two-sided adhesive tape to a non-active face of a die;
adhering a second side of the two-sided adhesive tape to a carrier to attach the die to the carrier;
dispensing a selected amount of an encapsulant onto the carrier adjacent to the attached die, the location and amount of encapsulant being selected to provide an exposed face of the encapsulant on a plane approximately coincident with an active face of the die;
applying an insulating layer to the face of at least one of the dispensed encapsulant and the die;
applying a first conductive layer to the face of the dispensed encapsulant to provide fan-out pads; and
applying a second conductive layer to the faces of the dispensed encapsulant and the die that connects the provided fan-out pads to electrical connections on the die's active face.

2. The method of claim 1, further comprising placing balls of a ball grid array onto the fan-out pads of the applied first conductive layer.

3. The method of claim 1, further comprising applying a passivation layer to the face of at least one of the dispensed encapsulant and the die.

4. The method of claim 1, further comprising singulating the electronic package from a plurality of electronic packages attached to the carrier.

5. The method of claim 1 wherein the die is a portion of a silicon wafer at the time that the first side of the two-sided adhesive tape is applied to the non-active face of the die, and the method further comprises singulating the die from the silicon wafer before attaching the die to the carrier.

6. The method of claim 1 wherein the first and second conductive layers are applied together as a single layer.

7. The method of claim 1 wherein the selected amount of encapsulant is dispensed by one of spin coating and screen printing.

8. The method of claim 1 wherein the applying and the dispensing are accomplished with processing equipment from one of the printed circuit board and liquid crystal display manufacturing industries.

9. An apparatus, comprising:
a carrier;
at least one semiconductor die supported by the carrier;
a film having adhesive on both sides that attaches a non-active face of the at least one die to the carrier;
an encapsulant material supported by the carrier and adjacent to the at least one die, the location and amount of encapsulant providing a surface of the encapsulant material on a plane approximately coincident with an active face of the die;
a plurality of fan-out pads supported by the provided encapsulant material surface; and
conductive traces supported by the provided encapsulant material surface that electrically connect the plurality of fan-out pads with electrical connections on the die's active face.

10. The apparatus of claim 9, further comprising at least one insulating layer supported by the provided encapsulant material surface and separating at least one conductive trace from another conductive trace.

11. The apparatus of claim 9, further comprising a passivation layer applied to the face of at least one of the encapsulant material and the die's active face.

12. The apparatus of claim 9, further comprising a solder ball array, wherein solder balls of the array electrically connect to the fan-out pads.

13. The method of claim 9 wherein the carrier is rectangular.

14. The method of claim 9 wherein the carrier is at least 370 mm×470 mm in size.

15. The method of claim 9 wherein the approximately coincident faces of the provided encapsulant material surface and the active face of the die are within 10 μm of coincidence.
